(19) United States
(12) Patent Application Publication
(10) Pub. No.: US 2014/0319637 A1
(43) Pub. Date: Oct. 30, 2014

(54) PHOTODETECTOR

(71) Applicant: HAMAMATSU PHOTONICS K.K., Hamamatsu-shi (JP)

(72) Inventors: Kazutoshi NAKAJIMA, Hamamatsu-shi (JP); Minoru NIIGAKI, Hamamatsu-shi (JP); Toru HIROHATA, Hamamatsu-shi (JP); Hiroyuki YAMASHITA, Hamamatsu-shi (JP); Wataru AKAHORI, Hamamatsu-shi (JP)

(73) Assignee: HAMAMATSU PHOTONICS K.K., Hamamatsu-shi (JP)

(21) Appl. No.: 14/259,509

(22) Filed: Apr. 23, 2014

Related U.S. Application Data
(60) Provisional application No. 61/816,365, filed on Apr. 26, 2013.

(30) Foreign Application Priority Data
Apr. 26, 2013 (JP) 2013-093263

(51) Int. Cl. H01L 31/0232

(52) U.S. Cl. CPC H01L 31/0232
USPC 257/432

(57) ABSTRACT

A photodetector 1A comprises an optical element 10A for generating an electric field component in a predetermined direction when light is incident thereon along the predetermined direction, the optical element 10A having a structure including first regions and second regions periodically arranged with respect to the first regions along a plane perpendicular to the predetermined direction; and a semiconductor layer 40, arranged on the other side opposite from one side in the predetermined direction with respect to the optical element 10A, having a semiconductor multilayer body 42 for generating a current according to the electric field component; each end part on the other side of the second regions being located closer to the other side than is each end part on the other side of the first regions; each first region being made of a dielectric body having a refractive index greater than that of each second region.

### CROSS-REFERENCE TO RELATED APPLICATIONS

This application claims priority to a Japanese Patent Application No. 2013-093263 filed on Apr. 26, 2013 and a Provisional Application No. 61/816,365 filed on Apr. 26, 2013 by the same Applicant, which are hereby incorporated by reference in their entirety.

### BACKGROUND OF THE INVENTION

1. Field of the Invention

The present invention relates to a photodetector.

2. Related Background Art

Known as photodetectors utilizing light absorption of quantum intersubband transitions are QWIP (quantum well type infrared optical sensor), QDIP (quantum dot infrared optical sensor), QCD (quantum cascade type optical sensor), and the like.

They utilize no energy bandgap transitions and thus have such merits as a high degree of freedom in designing wavelength ranges, relatively low dark current, and operability at room temperature.

Among these photodetectors, the QWIP and QCD are equipped with a semiconductor multilayer body having a periodic multilayer structure such as a quantum well structure or quantum cascade structure. This semiconductor multilayer body generates a current because of an electric field component in the stacking direction thereof only when light incident thereon has such an electric field component, and thus is not photosensitive to light having no electric field component in the stacking direction (planar waves incident thereon in the stacking direction thereof).

Therefore, in order for the QWIP or QCD to detect light, it is necessary for the light to be incident thereon such that a direction of vibration of an electric field of the light coincides with the stacking direction of the semiconductor multilayer body. When detecting a planar wave having a wavefront perpendicular to an advancing direction of light, for example, it is necessary for the light to be incident on the semiconductor multilayer body in a direction perpendicular to its stacking direction, which makes the photodetector cumbersome to use.

Hence, there has been known a photodetector which, for detecting light having no electric field component in the stacking direction of the semiconductor multilayer body, a thin gold film is disposed on a surface of the semiconductor multilayer body and periodically formed with holes each having a diameter not greater than the wavelength of the light (see W. Wu, et al., “Plasmonic enhanced quantum well infrared photodetector with high detectivity”, Appl. Phys. Lett., 96, 161107 (2010)(hereinafter, referred to as a “Non Patent Literature 1”)). In this example, the light is modulated so as to attain an electric field component in the stacking direction of the semiconductor multilayer body under a surface plasmon resonance effect on the thin gold film.

There has also been known a photodetector in which a light-transmitting layer is disposed on a surface of a semiconductor multilayer body, while a diffraction grating constituted by a pattern of irregularities and a reflective film covering the same are formed on the light-transmitting layer (see Japanese Patent Application Laid-Open No. 2000-156513 (hereinafter, referred to as a “Patent Literature 1”)). In this example, the light is modulated so as to have an electric field component in the stacking direction of the semiconductor multilayer body under the effects of diffraction and reflection of the incident light by the diffraction grating and reflective film.

Further, a photodetector having an entrance surface processed oblique with respect to the stacking direction of the semiconductor multilayer body has been known (see Japanese Patent Application Laid-Open No. 2012-69801 (hereinafter, referred to as a “Patent Literature 2”)). In this example, light entering from the entrance surface upon refraction repeats total reflection within the chip, thereby being modulated such as to have an electric field component in the stacking direction of the semiconductor multilayer body.

### SUMMARY OF THE INVENTION

### Technical Problem

Thus, for detecting light having no electric field component in the stacking direction of the semiconductor multilayer body, various techniques for modulating the light so as to provide it with an electric field component in the stacking direction have been proposed.

However, the photodetector disclosed in Non Patent Literature 1 has a QWIP structure simply stacking quantum wells having the same well width as a quantum well structure and requires a bias voltage from outside to be applied in order to operate as a photodetector, whereby adverse effects of the resulting dark current on the photosensitivity cannot be neglected.

For attaining effective photosensitivity, it is necessary for the photodetector disclosed in Patent Literature 1 to stack a number of periods of quantum well structures and form a number of light-absorbing layers.

In the photodetector disclosed in Patent Literature 2, the propagation direction of light caused by diffraction does not become completely horizontal and only partly contributes to photoelectric conversion, whereby sufficient photosensitivity cannot be obtained.

It is therefore an object of the present invention to provide a photodetector which, by using a semiconductor multilayer body having a quantum well structure, a quantum cascade structure, or the like, can detect light having no electric field component in the stacking direction of the semiconductor multilayer body.

### Solution to Problem

The photodetector in accordance with the present invention comprises an optical element for generating an electric field component in a predetermined direction when light is incident thereon along the predetermined direction, the optical element having a structure including first regions and second regions periodically arranged with respect to the first regions along a plane perpendicular to the predetermined direction; and a semiconductor layer, arranged on the other side opposite from one side in the predetermined direction with respect to the optical element, having a semiconductor multilayer body for generating a current according to the electric field component in the predetermined direction caused by the optical element; an each end part on the other side of the second regions being located closer to the other side than is each end part on the other side of the first regions; each first region being made of a dielectric body having a refractive index greater than that of each second region.

The optical element in this photodetector generates an electric field in a predetermined direction when light is incident thereon along the predetermined direction. This electric field component produces a current in the semiconductor multilayer body. Therefore, by using a semiconductor multilayer body having a quantum well structure, a quantum cascade structure, or the like, this photodetector can detect light having no electric field component in the stacking direction of the semiconductor multilayer body.

Here, each first region may be made of germanium or a compound containing germanium. The semiconductor layer may be made of a semiconductor having a refractive index greater than that of the second regions. These allow the optical element to generate the electric field component in the predetermined direction more efficiently from light having no electric field component in the predetermined direction.

The photodetector in accordance with the present invention comprises an optical element for generating an electric field component in a predetermined direction when light is incident thereon along the predetermined direction, the optical element having a structure including first regions and second regions periodically arranged with respect to the first regions along a plane perpendicular to the predetermined direction; and a semiconductor layer, arranged on the other side opposite from one side in the predetermined direction with respect to the optical element, having a semiconductor multilayer body for generating a current according to the electric field component in the predetermined direction caused by the optical element; each end part on the other side of the second region being located closer to the other side than is each end part on the other side of the first regions; each first region being made of a metal adapted to excite a surface plasmon with light.

The optical element in this photodetector generates an electric field in a predetermined direction when light is incident thereon along the predetermined direction. This electric field component produces a current in the semiconductor multilayer body. Therefore, by using a semiconductor multilayer body having a quantum well structure, a quantum cascade structure, or the like, this photodetector can detect light having no electric field component in the stacking direction of the semiconductor multilayer body.

In the photodetector of the present invention, a surface on the one side of the semiconductor layer may be formed with a depression, while each end part on the other side of the second regions may reach the depression. This allows the optical element to generate the electric field component in the predetermined direction more efficiently from light having no electric field component in the predetermined direction.

The second regions may be made of a plurality of kinds of materials. This also yields the effects of the present invention.

The semiconductor multilayer body may have a plurality of quantum cascade structures stacked along the predetermined direction, each quantum cascade structure including an active region for exciting an electron and an injector region for transporting the electron. In this case, an electron is excited in the active region and transported by the injector region, whereby a current is generated in the quantum cascade structure. Therefore, no bias voltage is required to be applied from the outside in order to operate the photodetector. Stacking a plurality of such quantum cascade structures along the predetermined direction yields a greater current, thereby raising the photosensitivity of the photodetector.

The semiconductor layer may further have a first contact layer formed on a surface on the one side of the semiconductor multilayer body and a second contact layer formed on a surface on the other side of the semiconductor multilayer body. In this case, the photodetector may further comprise a first electrode electrically connected to the first contact layer and a second electrode electrically connected to the second contact layer. These allow the current occurring in the semiconductor multilayer body to be detected efficiently.

The photodetector of the present invention may further comprise a substrate having the semiconductor layer and optical element sequentially stacked thereon from the other side. This can stabilize individual configurations of the photodetector.

In the optical element in the photodetector of the present invention, the second regions may be arranged with a period of 0.5 to 500 μm with respect to the first regions. This allows the electric field component in the predetermined direction to occur more efficiently when light is incident on the optical element along the predetermined direction.

The light incident on the optical element in the photodetector of the present invention may be an infrared ray. This allows the photodetector of the present invention to be used favorably as an infrared photodetector.

In the photodetector of the present invention, the optical element may generate the electric field component in the predetermined direction when light is incident thereon from the one side or from the other side through the semiconductor multilayer body.

### Advantageous Effects of Invention

The present invention can provide a photodetector which, by using a semiconductor multilayer body having a quantum well structure, a quantum cascade structure, or the like, can detect light having no electric field component in the stacking direction of the semiconductor multilayer body.

### BRIEF DESCRIPTION OF THE DRAWINGS

FIG. 1 is a plan view of the photodetector in accordance with a first embodiment of the present invention;

FIG. 2 is a sectional view taken along the line II-II of FIG. 1;

FIG. 3 is a partly enlarged sectional view of the optical element;

FIG. 4 is a sectional view of a modified example of the photodetector in accordance with the first embodiment of the present invention;

FIG. 5 is a sectional view of modified example of the photodetector in accordance with the first embodiment of the present invention;

FIG. 6 is a sectional view of the photodetector in accordance with a second embodiment of the present invention;

FIG. 7 is a sectional view of the photodetector in accordance with a third embodiment of the present invention;

FIG. 8 is a plan view of a modified example of the photodetector in accordance with the third embodiment of the present invention;

FIG. 9 is a sectional view taken along the line IX-IX of FIG. 8;

FIG. 10 is a plan view of a modified example of the photodetector in accordance with the third embodiment of the present invention;

FIG. 11 is a sectional view taken along the line XI-XI of FIG. 10;

FIG. 12 is a plan view of a photodetector in accordance with a fourth embodiment of the present invention;

FIG. 13 is a sectional view taken along the line XIII-XIII of FIG. 12;

FIG. 14 is a plan view of a photodetector in accordance with a modified example of the fourth embodiment of the present invention;

FIG. 15 is a sectional view taken along the line XV-XV of FIG. 14;

FIG. 16 is a plan view of a photodetector in accordance with modified example of the fourth embodiment of the present invention;

FIG. 17 is a sectional view of the photodetector in accordance with a fifth embodiment of the present invention;

FIG. 18 is a plan view of the photodetector in accordance with a sixth embodiment of the present invention;

FIG. 19 is a sectional view taken along the line XIX-XIX of FIG. 18;

FIG. 20 is a chart of an electric field intensity distribution according to an FDTD method; and

FIG. 21 is a graph of the electric field intensity calculated according to the depth of a depression in a semiconductor layer.

### DESCRIPTION OF THE PREFERRED EMBODIMENTS

In the following, preferred embodiments of the present invention will be explained with reference to the drawings. The same or equivalent parts in the drawings will be referred to with the same signs, while omitting their overlapping descriptions. The light to be detected by photodetectors of the embodiments (light incident on optical elements) is an infrared ray (light having a wavelength of 1 to 1000

### First Embodiment

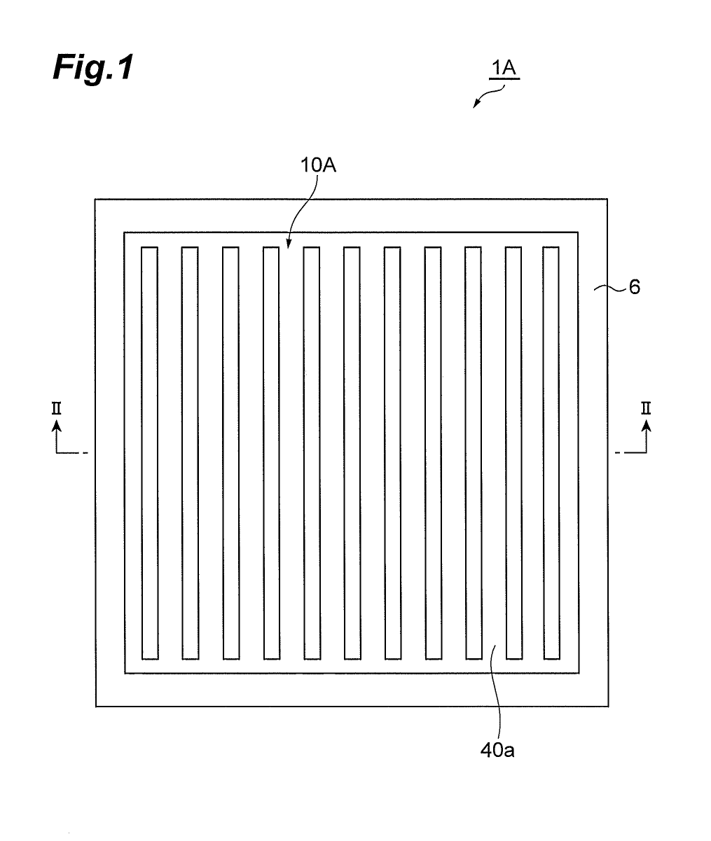

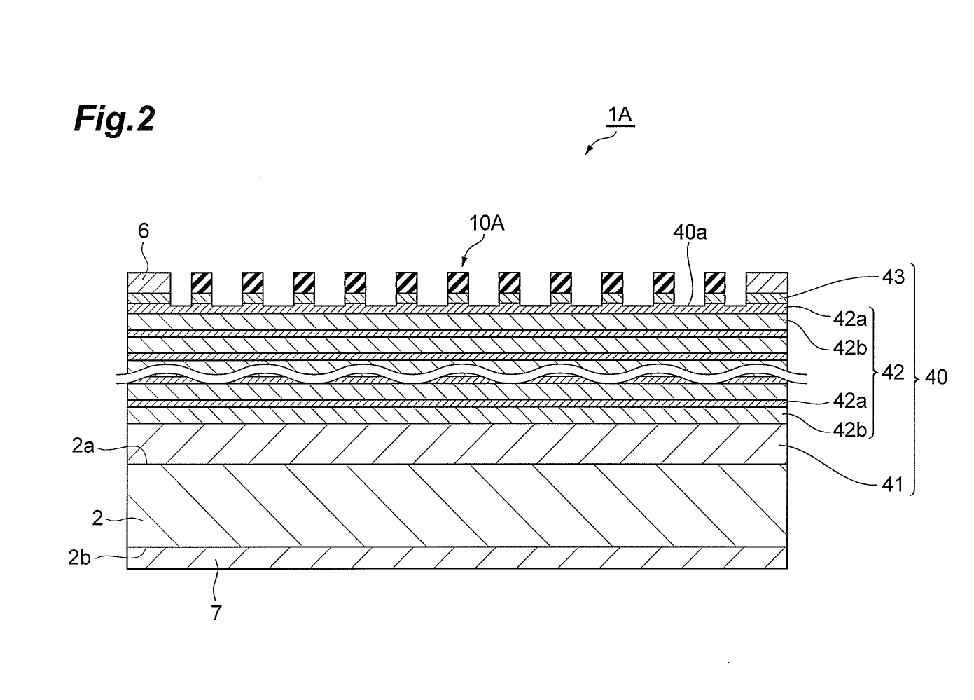

As FIGS. 1 and 2 illustrate, a photodetector 1A comprises a rectangular plate-shaped substrate 2 having a thickness of 300 to 500 μm made of n-type InP, on which a semiconductor layer 40, electrodes 6, 7, and an optical element 10A are stacked along a predetermined direction. This photodetector 1A is one which utilizes light absorption of quantum intersubband transitions in the semiconductor multilayer layer 40.

The semiconductor layer 40 is disposed all over a surface 2a on one side (one side in the predetermined direction) of the substrate 2. The semiconductor layer 40 is formed by stacking a contact layer (second contact layer) 41, a semiconductor multilayer body 42 in which a plurality of quantum cascade structures are layered, and a contact layer (first contact layer) 43 in sequence from the surface 2a of the substrate 2. At the center of the surface 40a of the semiconductor layer 40, the optical element 10A is disposed in a region smaller than the entire surface 40a. That is, the optical element 10A is arranged so as to be contained in the surface 40a of the semiconductor layer 40 when seen as a plane. In a peripheral region free of the optical element 10A on the surface 40a of the semiconductor layer 40, the electrode (first electrode) 6 is formed like a ring so as to surround the optical element 10A. On the other hand, another electrode (second electrode) 7 is disposed all over a surface 2b on the opposite side (the other side in the predetermined direction) of the surface 2a of the substrate 2.

The plurality of quantum cascade structures, each of which is designed in conformity to the wavelength of light to be detected, in the semiconductor multilayer body 42 are formed by being stacked such that an active region 42a adapted to absorb light and excite electrons is located on the optical element 10A side while an injector region 42b in charge of transporting the electrons unidirectionally is located on the side opposite therefrom. In the semiconductor multilayer body 42, quantum cascade structures each having a thickness of about 50 nm constituted by a set of the active region 42a and injector region 42b are stacked in a plurality of stages along the predetermined direction.

In each of the active and injector regions 42a, 42b, layers of InGaAs and InAlAs having energy bandgaps different from each other are alternately stacked with a thickness of several nm for each layer. In the active region 42a, the InGaAs layers are doped with n-type impurities such as silicon so as to function as well layers, while the InAlAs layers function as barrier layers holding the InGaAs layers. In the injector region 42b, on the other hand, the InGaAs and InAlAs layers not doped with impurities are stacked alternately. The number of stacked layers of InGaAs and InAlAs in the active and injector regions 42a, 42b in total is 16, for example. The structure of the active region 42a determines the center wavelength of the light to be absorbed.

The contact layers 41, 43, which are made of n-type InGaAs, are layers for electrically connecting the semiconductor multilayer body 42 to the electrodes 7, 6, respectively, in order to detect the current generated in the semiconductor multilayer body 42. Preferably, the contact layer 41 has a thickness of 0.1 to 1 μm. On the other hand, in order to make it easier for the optical element 10A to have effects which will be explained later on the quantum cascade structures, the contact layer 43 is as thin as possible and preferably 5 to 100 nm in particular. The electrodes 6, 7 are ohmic electrodes made of Ti/Au.

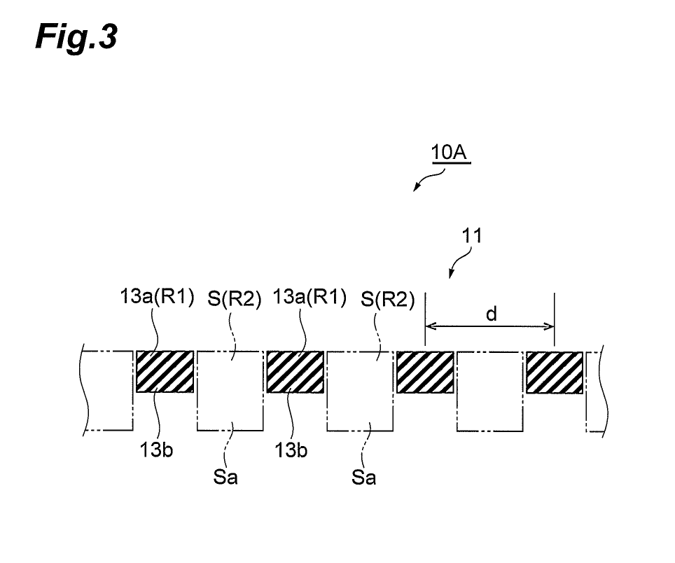

The optical element 10A generates an electric field component in a predetermined direction when light is incident thereon from one side in the predetermined direction. As FIG. 3 illustrates, the optical element 10A comprises a structure 11, which has first regions R1 and second regions R2 periodically arranged with the first regions R1 along a plane perpendicular to the predetermined direction with a period d of 0.5 to 500 μm depending on the wavelength of the incident light (not longer than the wavelength of the incident light). The wavelength region of the light detected by the photodetector 1A is determined by the period d of the optical element and thus is designed such as to include a center wavelength at which electrons are excited by the semiconductor multilayer body 42.

The first regions R1 are formed into rod-shaped bodies 13a, made of a dielectric body (e.g., germanium, whose refractive index is 4.0) having a thickness in the predetermined direction and extending like rods along a plane perpendicular to the predetermined direction. With spaces (air) S which are the second regions R2, the rod-shaped bodies 13a form stripes (see also FIG. 1). As FIG. 3 illustrates, end parts Sa on the other side of the spaces S project more to the other side than do end parts 13b on the other side of the rod-shaped bodies 13a. Preferably, the first regions R1 have a thickness of 10 nm to 2 μm.

As FIG. 2 illustrates, at the center surface on one side of the semiconductor layer 40, the contact layer 43 is partly removed so as to leave stripes, thereby forming depressions (thus yielding a so-called recess form). The optical element 10A is disposed on the semiconductor layer 40 such that the end parts Sa of the second regions R2 projecting to the other side reach the depressions. Here, the end parts 13b on the other side of the first regions R1 of the optical element 10A are in contact with the surface on one side of the contact layer 43 left as stripes, while the end parts Sa of the second regions R2 projecting to the other side are held between the side faces of the stripes of the contact layer 43. Preferably, the depressions have a depth of 5 to 500 nm.

Such forms of the surface 40a of the semiconductor layer 40 and optical element 10A can be produced by layering a dielectric body all over a flat surface of a contact layer before forming the depressions and then patterning the dielectric body and contact layer into stripes by dry etching. The dry etching may reach the semiconductor multilayer body 42. FIG. 2 illustrates a state where the dry etching has reached a part of the active region 42a of the semiconductor multilayer body 42.

In the above-mentioned photodetector 1A, the magnitudes of refractive indexes in materials have a relationship of the first region R1>semiconductor layer 40>second region R2.

Since thus constructed photodetector 1A is equipped with the above-mentioned optical element 10A, light incident on the optical element 10A from one side in the predetermined direction (e.g., a planar wave incident thereon in the stacking direction of the semiconductor multilayer body 42), if any, is modulated by the difference between the refractive indexes of the first and second regions R1, R2 periodically arranged along a plane perpendicular to the predetermined direction in the structure 11 and then exits from the other side in the predetermined direction. Here, light having no electric field component in the predetermined direction is efficiently modulated so as to have an electric field component in the predetermined direction. Since the surface 40a of the semiconductor layer 40 is formed with depressions, the magnitude of the electric field is enhanced as compared with the case where no depressions are formed. The facts that the magnitudes of refractive indexes in materials have a relationship of the first region R1>semiconductor layer 40>second region R2, the period d in the arrangement of the first and second regions R1, R2 is 0.5 to 500 μm, and the like enable the light to be modulated more efficiently.

The electric field component in the predetermined direction generated by the above-mentioned effects of the optical element 10A is also an electric field component of the semiconductor multilayer body 42 and thus excites electrons in the active region 42a in the quantum cascade structure, while the injector region 42b unidirectionally transports the electrons, thereby producing a current in the quantum cascade structure. This current is detected through the electrodes 6, 7. That is, this photodetector 1A can detect light having no electric field component in the stacking direction of the semiconductor multilayer body 42. Since electrons are supplied from the electrode 6, a current continuity condition is satisfied.

As can be seen from a simulation which will be explained later, the electric field component in the predetermined direction attains the highest intensity at the interface between the optical element 10A and the semiconductor layer 40, but its intensity is not zero even in a deep region of the semiconductor layer 40 and exists while decaying with depth. Since the semiconductor multilayer body 42 has a plurality of stages of quantum cascade, photoexcited electrons are also effectively generated by electric field components reaching deep regions. Therefore, the photosensitivity of the photodetector can be considered to be enhanced further.

The photodetector 1A of the present invention further comprises the substrate 2 for supporting the semiconductor layer 40 and optical element 10A and thus stabilizes the individual configurations of the photodetector 1A.

The photodetector disclosed in Non Patent Literature 1, which has conventionally been known, employs a QWIP structure in which quantum wells having the same well width are simply stacked as a quantum well structure and requires a bias voltage to be applied from the outside in order to operate as a photodetector, whereby adverse effects of the resulting dark current on the photosensitivity cannot be neglected. In the photodetector 1A of the present invention, by contrast, the injector region 42b is designed such as to unidirectionally transport the electrons excited in the active region 42a, which makes it unnecessary to apply a bias voltage from the outside in order to operate as a photodetector, while the electrons excited by light migrate scatteringly between quantum levels without the bias voltage, whereby the dark current is very small. Therefore, the photodetector 1A can detect weaker light having no electric field component in the stacking direction of the semiconductor multilayer body 42 with a high sensitivity. It can detect weaker light than do detectors using PbS(Se) and HgCdTe conventionally known as mid-infrared photodetectors, for example.

The photodetector disclosed in Non Patent Literature 1 utilizes a surface plasmon resonance in order to generate an electric field component in the predetermined direction. This blocks a part of the incident light (infrared rays here) with a thin gold film, while the surface plasmon resonance itself tends to incur a large energy loss, whereby the photosensitivity may deteriorate. Further, the surface plasmon resonance, which is a state of resonance of vibrations occurring as a result of combinations of free electrons in a metal with electric field components of light and the like, has a limitation in that it is essential for free electrons to exist on the light entrance surface in order to utilize the surface plasmon resonance. By contrast, the photodetector 1A of the present invention is advantageous in that, since each of the first and second regions R1, R2 is transparent to the incident light, while no surface plasmon resonance is used for modulating light, the deterioration in photosensitivity feared in the photodetector disclosed in Non Patent Literature 1 does not occur, and materials for use are not limited to metals having free electrons.

The photodetector disclosed in Patent Literature 1 forms a diffraction grating on a surface of a light-transmitting layer and thus has a low degree of freedom in design as a photodetector. In the photodetector 1A of this embodiment, by contrast, the optical element 10A is formed separately from the semiconductor layer 40, thus leaving a large room for selecting materials and choosing techniques for forming and processing the optical element 10A. Hence, the photodetector 1A of this embodiment has a high degree of freedom in design corresponding to the wavelength of incident light, desirable photosensitivity, and the like.

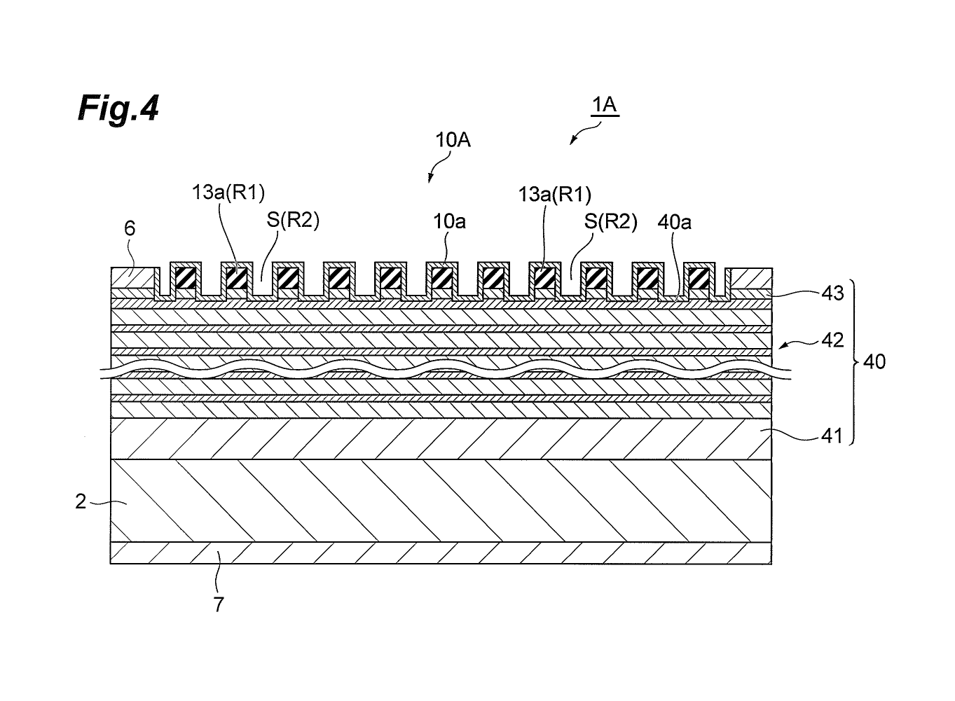

In the photodetector 1A of this embodiment, as FIG. 4 illustrates, the optical element 10A may be provided with a passivation film 10a made of an insulating material such as SiO₂ or SiN. In this case, the second region R2 is constituted by a plurality of kinds of materials, i.e., air and the passivation film 10a. Providing the passivation film 10a is expected to lower the efficiency in generating the electric field component in the predetermined direction more or less, but can keep the surface of the optical element 10A from being damaged by moisture and the like, thereby being effective in preventing the device from deteriorating.

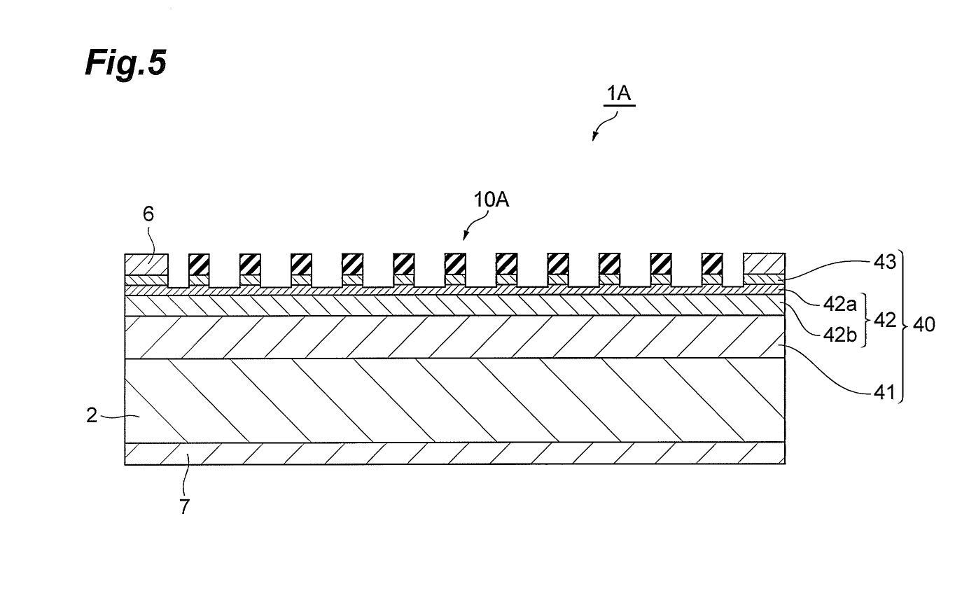

As FIG. 5 illustrates, the photodetector 1A of the above-mentioned first embodiment may have one stage instead of a plurality of stages of quantum cascade structures. This can also exhibit the above-mentioned electric field enhancement effects, thereby yielding an effective photosensitivity.

### Second Embodiment

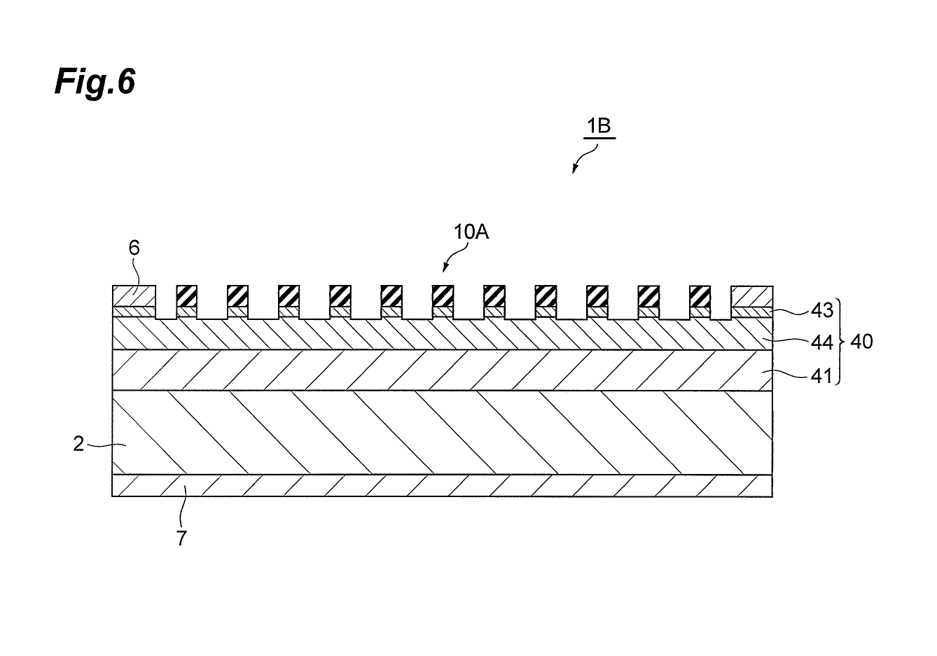

Another mode of the photodetector will now be explained as the second embodiment of the present invention. A photodetector 1B of the second embodiment illustrated in FIG. 6 differs from the photodetector 1A of the first embodiment in that it has a typical quantum well structure instead of the quantum cascade structure.

A semiconductor multilayer body 44 in this embodiment is equipped with a multiple quantum well structure designed such as to conform to the wavelength of light to be detected and has a thickness on the order of 50 nm to 1 μM. Specifically, layers of InGaAs and InAlAs having energy bandgaps different from each other are alternately stacked with a thickness of several nm for each layer.

When a bias voltage is applied from the outside to thus constructed photodetector 1B through the electrodes 6, 7, a potential gradient is formed within the semiconductor multilayer body 44. An electric field component in a predetermined direction caused by an action of an optical element excites electrons in the quantum well structure, and these electrons are detected through the electrodes 6, 7 according to the potential gradient. That is, this photodetector 1B can detect light having no electric field component in the stacking direction of the semiconductor multilayer body 44. Since electrons are supplied from the electrode 6, a current continuity condition is satisfied. This embodiment exhibits the above-mentioned electric field enhancement effect, so that the dark current caused by the bias voltage has a relatively small influence on the photosensitivity, whereby the photosensitivity is kept favorably.

### Third Embodiment

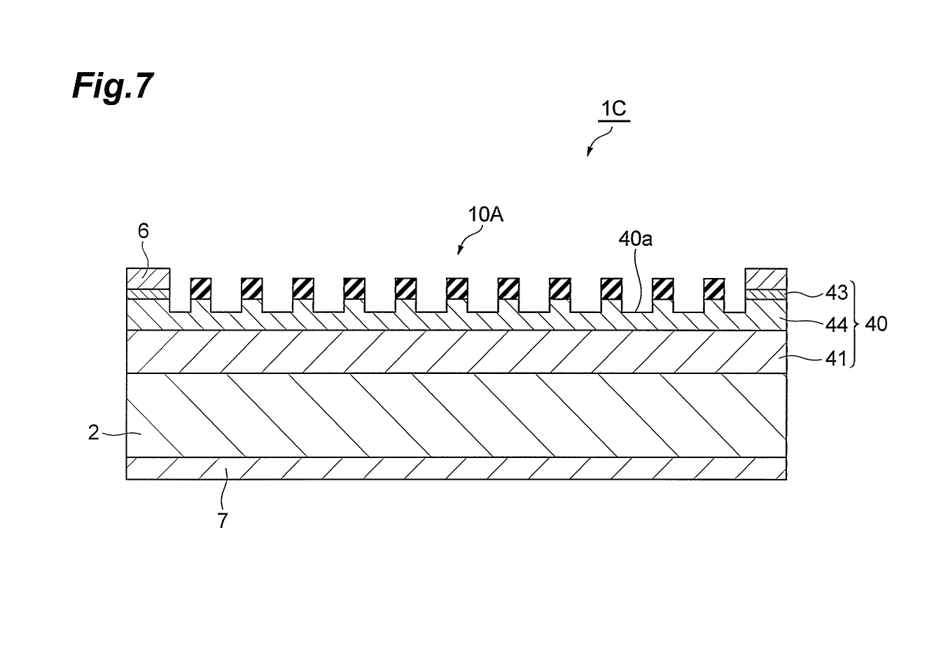

Another mode of the photodetector will now be explained as the third embodiment of the present invention. A photodetector 1C of the third embodiment illustrated in FIG. 7 differs from the photodetector 1B of the second embodiment in that the semiconductor layer 40 has no contact layer on its surface 40a (except for the part directly under the electrode 6).

As will be seen from a simulation which will be explained later, the electric field component in a predetermined direction caused by the light incident on the optical element 10A from one side in the predetermined direction appears most strongly in the vicinity of the surface on the other side of the optical element 10A. Therefore, the photodetector 1C of this embodiment, in which the optical element 10A and the semiconductor multilayer body 44 are in direct contact with each other, exhibits a higher photosensitivity than in the case where the contact layer 43 intervenes.

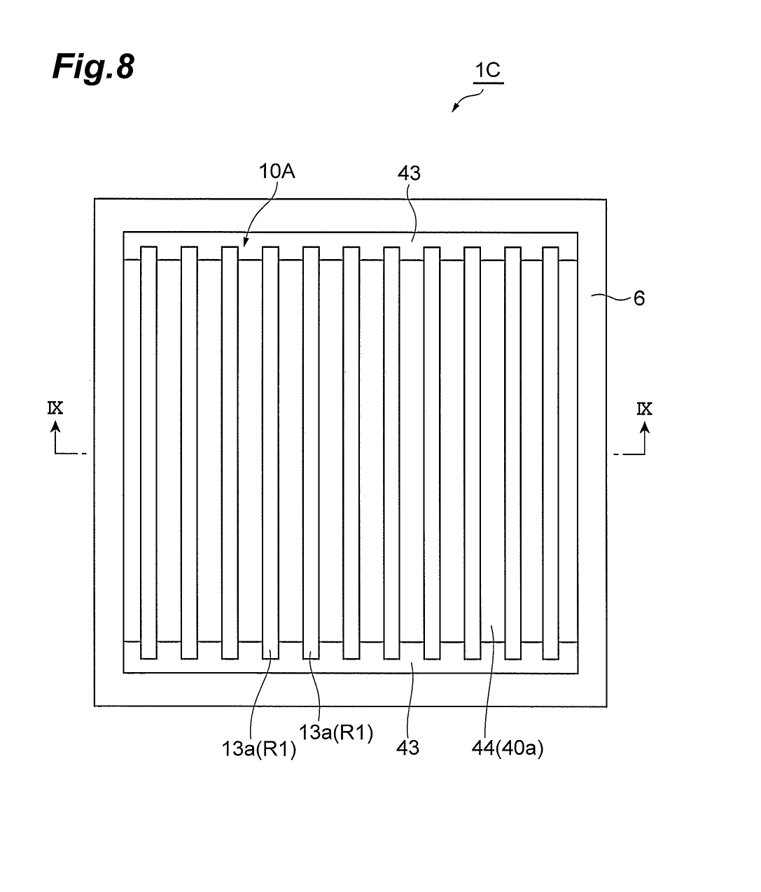

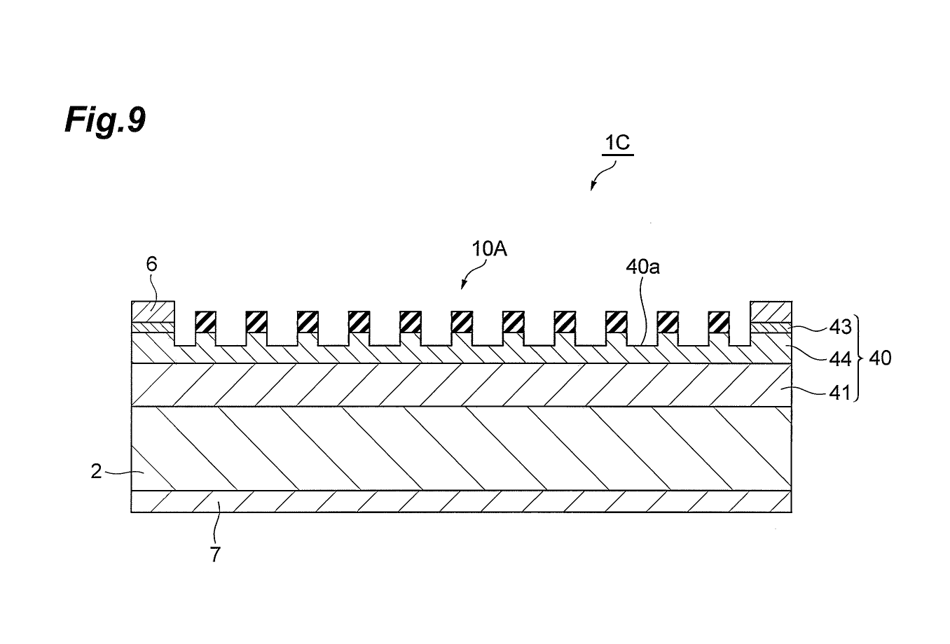

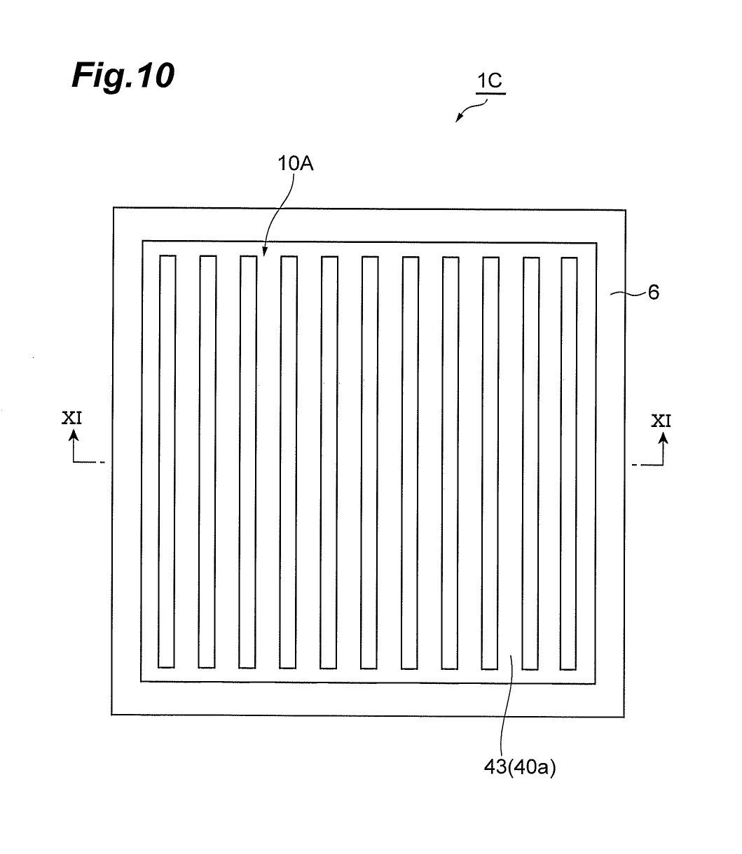

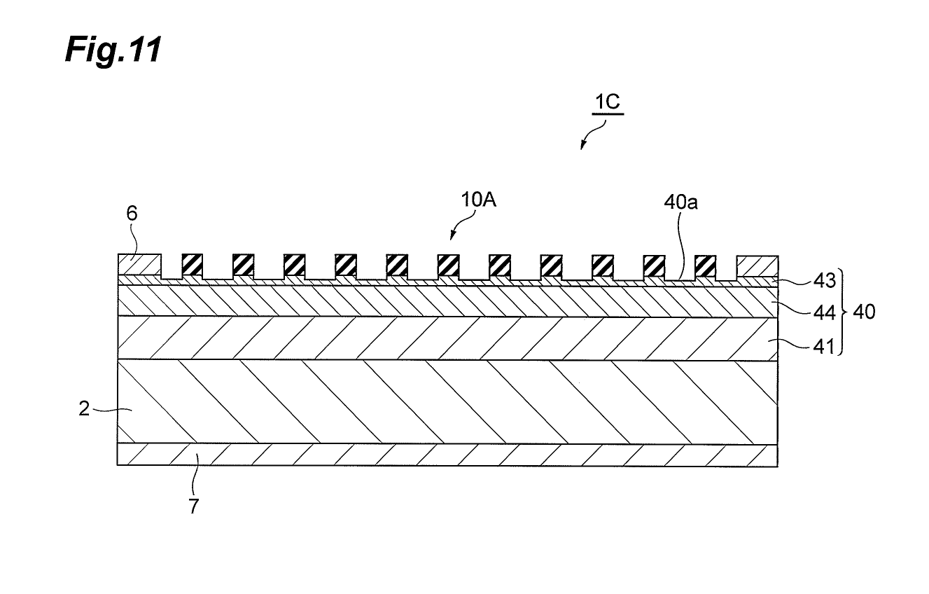

As FIGS. 8 and 9 illustrate, the photodetector 1C of the above-mentioned third embodiment may be constructed such that contact layers are disposed so as to link the rod-shaped bodies 13a of the optical element 10A together at their both longitudinal end parts. When forming depressions on the surface 40a of the semiconductor layer 40, the dry etching may be stopped in the middle of the contact layer 43, so as to leave the contact layer 43 on all over the semiconductor layer 40 as illustrated in FIGS. 10 and 11. In this mode, the contact layer 43 may be formed thicker beforehand. Leaving the contact layer 43 allows the current to flow more smoothly between the electrodes 6, 7, whereby loss can be reduced more.

### Fourth Embodiment

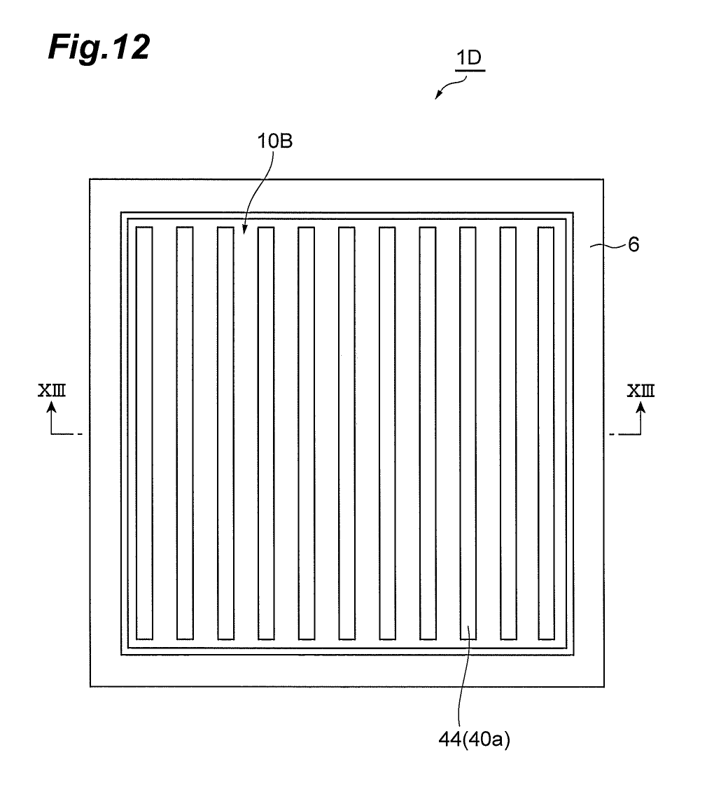

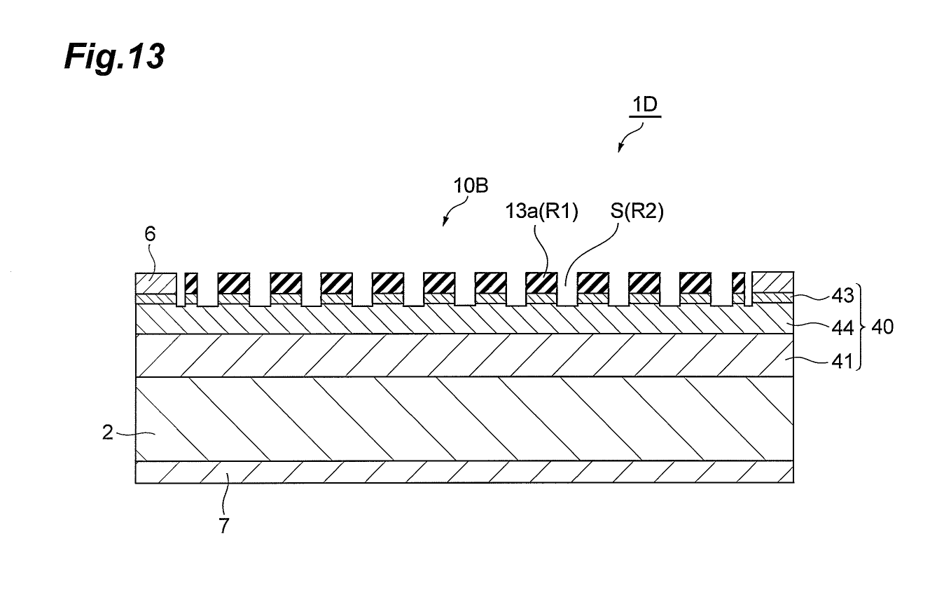

Another mode of the photodetector will now be explained as the fourth embodiment of the present invention. A photodetector 1D of the fourth embodiment illustrated in FIGS. 12 and 13 differs from the photodetector 1B of the second embodiment in that it comprises an optical element 10B having a different form in place of the optical element 10A.

In the optical element 10B, first regions R1 (rod-shaped bodies 13a) made of a dielectric body (e.g., germanium) form stripes with spaces (air) S which are second regions R2. The first regions R1 are linked together at their both longitudinal end parts by a dielectric material constituting the first regions R1. In other words, the optical element 10B has such a form in which a film made of a dielectric body is periodically provided with slit-like holes. The surface 40a of the semiconductor layer 40 is seen through the slit-like holes. The photodetector 1D exhibits its functions in such a mode as well.

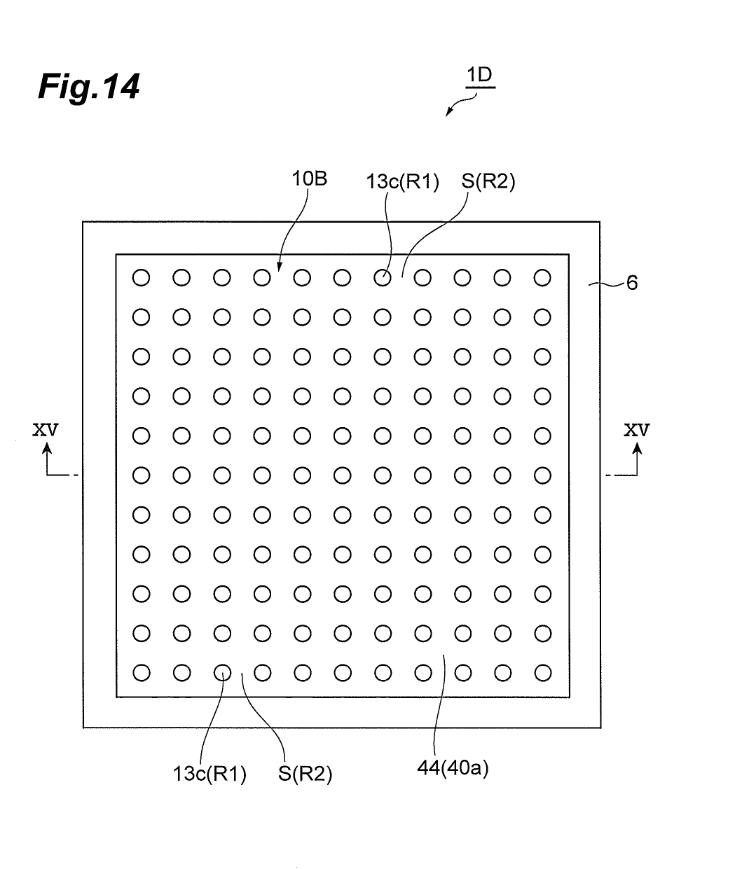

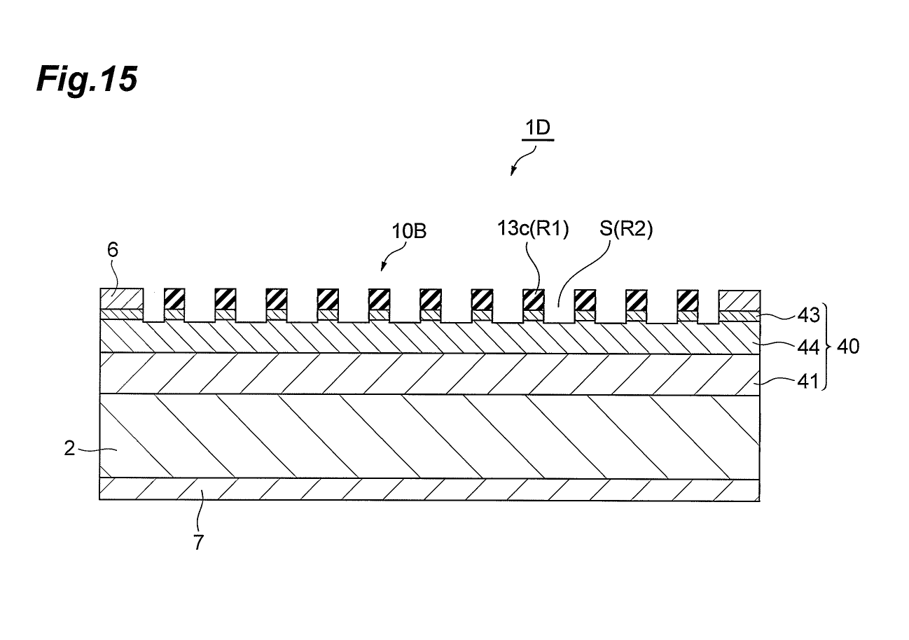

In the photodetector 1D of the above-mentioned fourth embodiment, its optical element 10B may be in another mode. For example, as FIGS. 14 and 15 illustrate, the first regions R1 may be cylindrical bodies 13c, each having a height in a predetermined direction, arranged in a square lattice along a plane perpendicular to the predetermined direction in a planar view. Here, the second regions R2 are a space S between the cylindrical bodies 13c. While light which can generate an electric field component in the predetermined direction is limited to one polarized in the direction in which the slit-shaped through holes are arranged in the photodetector 1D of the above-mentioned fourth embodiment, it increases to two kinds of polarization directions in the photodetector 1D equipped with the optical element 10B illustrated in FIGS. 14 and 15, since the first and second regions R1, R2 are periodically arranged in two-dimensional directions.

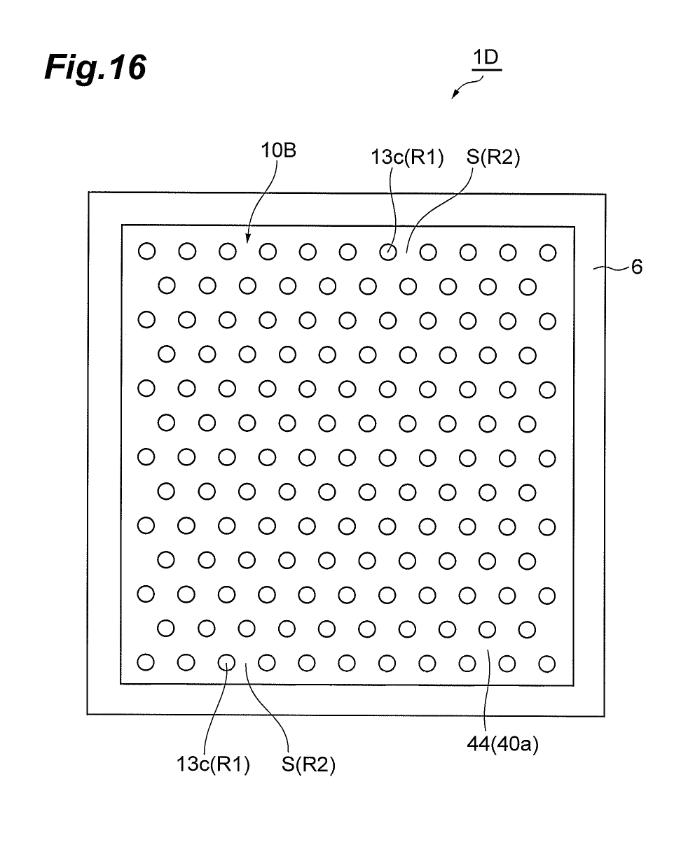

The cylindrical bodies 13c may be arranged in a triangular lattice as illustrated in FIG. 16 instead of the square lattice. This can further reduce the dependence on the polarization direction of the incident light as compared with the square lattice arrangement.

### Fifth Embodiment

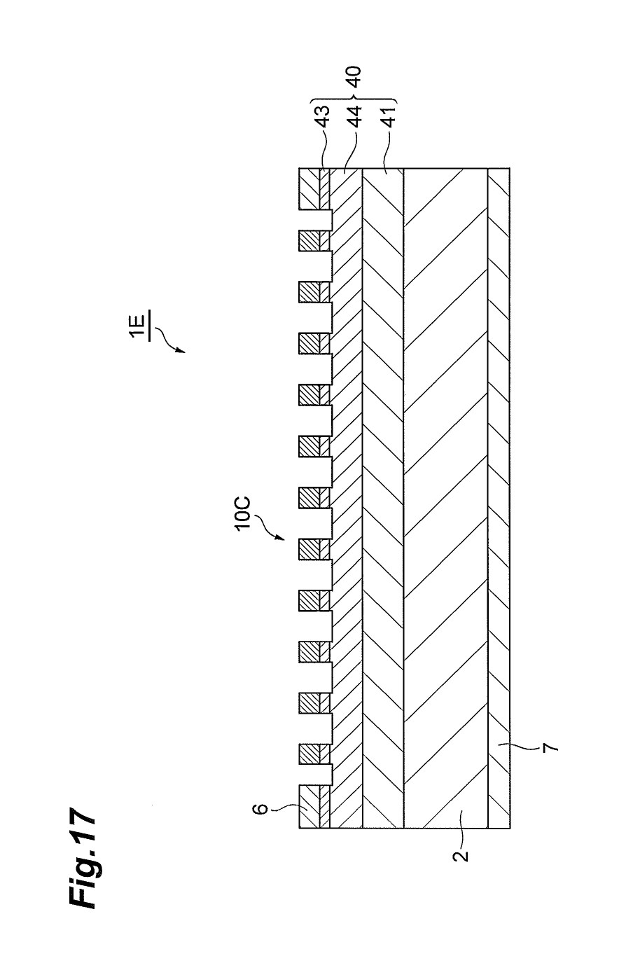

Another mode of the photodetector will now be explained as the fifth embodiment of the present invention. A photodetector 1E of the fifth embodiment illustrated in FIG. 17 differs from the photodetector 1B of the second embodiment in that it comprises an optical element 10C made of gold in place of the optical element 10A.

Since thus constructed photodetector 1E is equipped with the optical element 10C in which the first regions R1 made of gold having free electrons and the second regions R2 made of air are periodically arranged along a plane perpendicular to the predetermined direction, a surface plasmon is excited by a surface plasmon resonance when light is incident on the optical element 10C from one side in the predetermined direction. An electric field in the predetermined direction occurs at this time, and light can subsequently be detected by the same action as with the photodetector 1B of the second embodiment.

### Sixth Embodiment

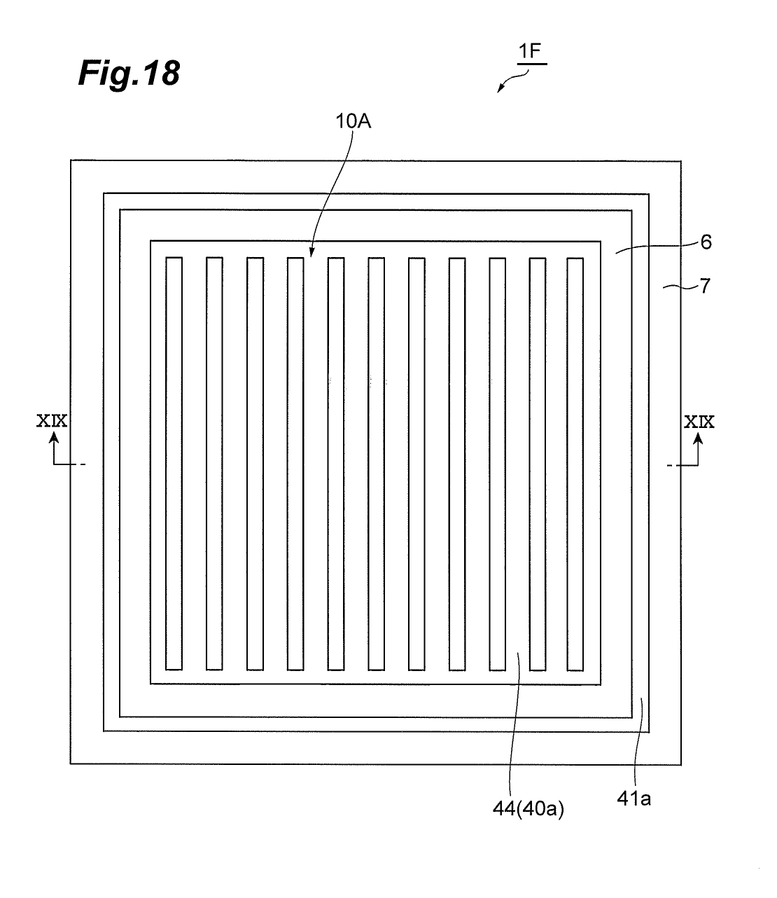

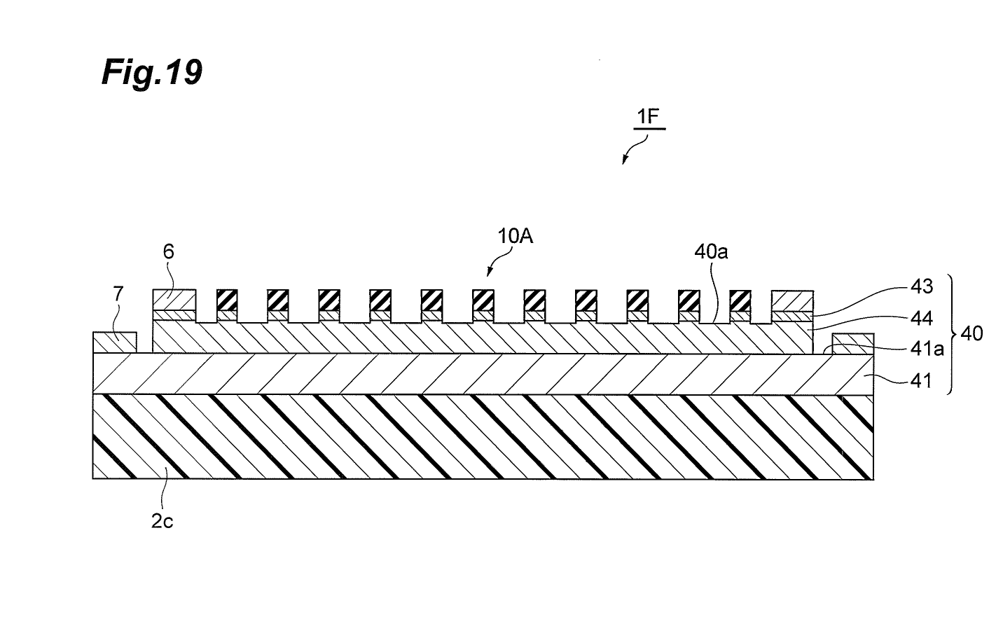

Another mode of the photodetector will now be explained as the sixth embodiment of the present invention. A photodetector 1F of the sixth embodiment illustrated in FIGS. 18 and 19 differs from the photodetector 1B of the second embodiment in that a semi-insulating type InP substrate 2c is used as a substrate, that the semiconductor multilayer body 44 has an area smaller than the surface 41 a of the contact layer 41 and is disposed at the center of the surface 41 a instead of the entire surface, and that the electrode 7 is formed like a ring so as to surround the semiconductor multilayer body 44 in a marginal region which is free of the semiconductor multilayer body 44 on the surface 41 a of the contact layer 41. This electrode 7 can be formed by stacking the contact layer 41, semiconductor multilayer body 44, and contact layer 43 and then etching the contact layer 43 and semiconductor multilayer body 44 away, so as to expose the surface 41 a of the contact layer 41.

Since a surface of the substrate 2c on the side opposite from the contact layer 41 is free of electrodes, light can be made incident on the photodetector 1F from the rear side thereof (the other side in the predetermined direction), so as to be detected. This can prevent the optical element 10A from reflecting and absorbing the incident light, thereby further enhancing the photosensitivity. Thus using the substrate 2c of a semi-insulating type with less electromagnetic induction makes it easier to achieve lower noise, higher speed, or integrated circuits with amplifier circuits and the like. It also has the merit of enhancing the probability of development into image sensors and the like in particular, since light can easily be made incident on the photodetector 1F in a package, in a state mounted on a submount, an integrated circuit, or the like by flip chip bonding.

This embodiment may also use an n-type InP substrate as the substrate.

While preferred embodiments of the present invention are explained in the foregoing, the present invention is not limited thereto. The above-mentioned embodiments may freely combine modes of the optical element with those of the semiconductor layer. For example, the optical element in the third, fourth, or fifth embodiment may be combined with the quantum cascade structure (the mode in which a plurality of stages of quantum cascade structures are stacked along the predetermined direction or the mode provided with one stage of quantum cascade structure) in the first embodiment.

While the above-mentioned embodiments relate to an example in which the semiconductor multilayer body formed on the InP substrate is constituted by InAlAs and InGaAs, it may be constituted by InP and InGaAs, AlGaAs and GaAs formed on a GaAs substrate, or any other semiconductor multilayer structures such as those made of GaN and InGaN can be employed as long as a quantum level is formed thereby.

While the first embodiment employs germanium (Ge) as a dielectric body having a high refractive index which is a material for the optical element 10A, it is not restrictive. Examples of other materials include germanium-containing compounds. An example of them is silicon-germanium (SiGe). While the fifth embodiment employs gold (Au) as a material for the optical element 10A, other metals having low electric resistance such as aluminum (Al) and silver (Ag) may also be used. Metals constituting the ohmic electrodes 6, 7 in the embodiments are not limited to those set forth here. Thus, the present invention can be employed in ranges of variations of device forms which are typically thought of.

While the above-mentioned embodiments illustrate a mode in which the second regions are made of air, the second regions may be constituted by materials other than air as long as the refractive index is higher in the first regions than in the second regions. Here, it will be more preferred for the material to have such a refractive index that the first region>semiconductor layer>second region in terms of refractive index.

In the photodetector of the present invention, the optical element may generate an electric field component in a predetermined direction either when light is incident thereon from one side in the predetermined direction or from the other side in the predetermined direction through the semiconductor multilayer body. That is, the optical element of the present invention generates an electric field in a predetermined direction when light is incident thereon along the predetermined direction.

### EXAMPLES

In the optical element in accordance with the present invention, an electric field intensity distribution near the light exit side was calculated by a simulation.

The optical element 10A and semiconductor layer 40 of the first embodiment were used. Their sizes were set as follows:

Period d=1.6 μm
First region: germanium (refractive index 4.0) with a thickness of 0.8 μm and a width of 0.8 μm
Second region: air (refractive index 1.0) with a thickness of 0.83 μm and a width of 0.8 μm
Contact layer thickness: 20 μm
Semiconductor multilayer body thickness: 50 nm
Depth of depressions formed in the semiconductor layer: 30 nm

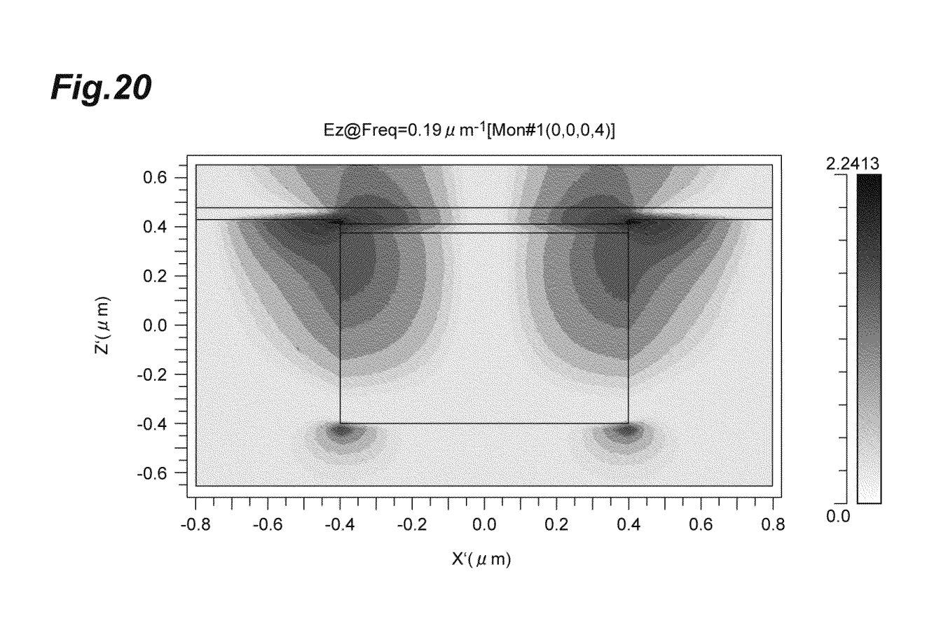

The electric field distribution was calculated by a method of successive approximation known as FDTD (Finite-Difference Time-Domain). FIG. 20 illustrates the results. Here, the incident light was a planar wave having a wavelength of 5.2 μm directed from the lower side to the upper side in FIG. 20 (i.e., in a predetermined direction). The direction of polarization was a direction in which the rod-shaped bodies 13a of the optical element 10A align. FIG. 20 indicates the intensity of an electric field component perpendicular to a plane formed by the first and second regions R1, R2 in the optical element 10A (a plane perpendicular to the predetermined direction).

The incident light is a uniform planar wave having an electric field component only in a lateral direction. It is seen from FIG. 20 that an electric field component in a predetermined direction not included in the incident light is newly generated by the periodic arrangement of the first regions (germanium) and second regions (air). The electric field component in the predetermined direction is also seen to attain the highest intensity at the interface between the optical element 10A and the semiconductor layer 40.

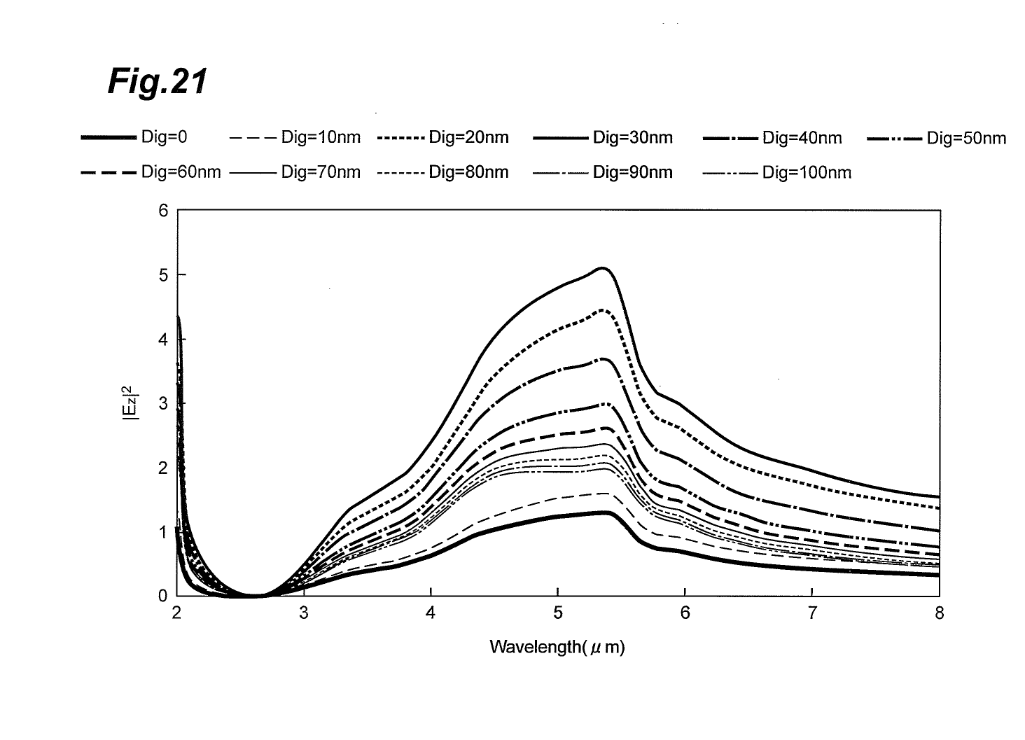

FIG. 21 illustrates the electric field intensity in the predetermined direction at a given point within the semiconductor multilayer body 42, which is a light-absorbing layer, as a result of calculation according to the depth of depressions in the semiconductor layer. The forms and sizes other than the depth of depressions are the same as those used for the calculation in FIG. 20. It is seen from this model that the vertical electric field intensity is the highest when the depth of depressions is 30 nm. It is also seen that a greater electric field occurs even when the depth of depressions is 100 nm than when no depressions are formed at all (i.e., when each end part on the other side of the second regions does not project more to the other side than does each end part on the other side of the first regions).

### REFERENCE SIGNS LIST

1A, 1B, 1C, 1D, 1E, 1F . . . photodetector; 2, 2c . . . substrate; 6 . . . electrode (first electrode); 7 . . . electrode (second electrode); 10A, 10B, 10C . . . optical element; 11 . . . structure; 13b . . . end part (end part on the other side of the first region); 40 . . . semiconductor layer; 40a . . . surface (surface on one side of the semiconductor layer); 41 . . . contact layer (second contact layer); 42, 44 . . . semiconductor multilayer body; 42a . . . active region; 42b . . . injector region; 43 . . . contact layer (first contact layer); R1 . . . first region; R2 . . . second region; Sa . . . end part (end part on the other side of the second region)

What is claimed is:

1. A photodetector comprising:
an optical element for generating an electric field component in a predetermined direction when light is incident thereon along the predetermined direction, the optical element having a structure including first regions and second regions periodically arranged with respect to the first regions along a plane perpendicular to the predetermined direction; and
a semiconductor layer, arranged on the other side opposite from one side in the predetermined direction with respect to the optical element, having a semiconductor multilayer body for generating a current according to the electric field component in the predetermined direction caused by the optical element;
wherein each end part on the other side of the second regions is located closer to the other side than is each end part on the other side of the first regions; and
wherein each first region is made of a dielectric body having a refractive index greater than that of each second region.

2. A photodetector according to claim 1, wherein each first region is made of germanium or a compound containing germanium.

3. A photodetector according to claim 1, wherein each first region is made of germanium.

4. A photodetector according to claim 1, wherein the semiconductor layer is made of a semiconductor having a refractive index greater than that of the second regions.

5. A photodetector comprising:
an optical element for generating an electric field component in a predetermined direction when light is incident thereon along the predetermined direction, the optical element having a structure including first regions and second regions periodically arranged with respect to the first regions along a plane perpendicular to the predetermined direction; and
a semiconductor layer, arranged on the other side opposite from one side in the predetermined direction with respect to the optical element, having a semiconductor multilayer body for generating a current according to the electric field component in the predetermined direction caused by the optical element;
wherein each end part on the other side of the second regions is located closer to the other side than is each end part on the other side of the first regions; and
wherein each first region is made of a metal adapted to excite a surface plasmon with light.

6. A photodetector according to claim 1, wherein a surface on the one side of the semiconductor layer is formed with a depression, and wherein each end part on the other side of the second regions reaches the depression.

7. A photodetector according to claim 1, wherein the second regions are made of a plurality of kinds of materials.

8. A photodetector according to claim 1, wherein the semiconductor multilayer body has a plurality of quantum cascade structures stacked along the predetermined direction; and
wherein each of the quantum cascade structures includes an active region for exciting an electron and an injector region for transporting the electron.

9. A photodetector according to claim 1, wherein the semiconductor layer further has:
a first contact layer formed on a surface on the one side of the semiconductor multilayer body; and
a second contact layer formed on a surface on the other side of the semiconductor multilayer body.

10. A photodetector according to claim 9, further comprising:
a first electrode electrically connected to the first contact layer; and
a second electrode electrically connected to the second contact layer.

11. A photodetector according to claim 9, further comprising a substrate having the semiconductor layer and optical element sequentially stacked thereon from the other side.

12. A photodetector according to claim 1, wherein the second regions are arranged with a period of 0.5 to 500 μm with respect to the first regions.

13. A photodetector according to claim 1, wherein the light is an infrared ray.

14. A photodetector according to claim 1, wherein the optical element generates the electric field component in the predetermined direction when light is incident thereon from the one side.

15. A photodetector according to claim 1, wherein the optical element generates the electric field component in the predetermined direction when light is incident thereon from the other side through the semiconductor multilayer body.
